(19) United States
(12) Patent Application Publication
(10) Pub. No.: US 2010/0203713 A1
(43) Pub. Date: Aug. 12, 2010

(54) METHOD OF MANUFACTURING ELECTRONIC DEVICE

(76) Inventors: Tadahiro Ohmi, Miyagi (JP); Makoto Fujimura, Tokyo (JP); Tadashi Koike, Gifu (JP); Akinori Bamba, Gifu (JP); Akihiro Kobayashi, Gifu (JP); Kohei Watanuki, Tokyo (JP)

Correspondence Address: FOLEY AND LARDNER LLP;SUITE 500, 3000 K STREET NW, WASHINGTON, DC, 20007, US

(21) Appl. No.: 12/733,595

(22) PCT Filed: Sep. 5, 2008
(86) PCT No.: PCT/JP2008/066080

§ 371 Date: Mar. 10, 2010

(30) Foreign Application Priority Data
Sep. 11, 2007 (JP) 2007-234974

(51) Int. Cl. H01L 21/28; H01L 21/20

(52) U.S. Cl. 438/481; 438/585; 257/E21.19; 257/E21.09

(57) ABSTRACT

An object of this invention is to provide a method for manufacturing an electronic device wherein a conductor layer is uniformly formed on a substrate having a super large area. In the method for manufacturing the electronic device, a metal film for forming a gate electrode is selectively embedded in a transparent resin film formed on a substrate, and the metal film is formed by sputtering directly on the substrate at the gate electrode portion, and on an insulating coat film on portions other than the gate electrode portion. The metal film on the insulating coat film is removed by chemical liftoff with removal of the insulating coat film by etching.

### TECHNICAL FIELD

This invention relates to an electronic device including a thin film transistor (TFT) or the like and its manufacturing method and, further, relates to a display device (organic EL device, inorganic EL device, liquid crystal display device, or the like) using TFTs, a circuit board, and other electronic devices and their manufacturing method.

### BACKGROUND ART

Generally, a display device such as a liquid crystal display device, an organic EL device, or an inorganic EL device has conductive patterns such as a wiring pattern and an electrode pattern formed and patterned on a substrate having a flat main surface. Further, various films, an electrode film, and so on necessary for elements that constitute the display device are also disposed on the substrate.

In recent years, there is a growing demand for making a size of such display device bigger. In order to form a large-size display device, it is necessary to form as many as display elements on a substrate with high accuracy and to electrically connect these elements to a wiring pattern. In this case, insulating films, TFTs (thin film transistors), light emitting elements, and so on are formed, in addition to the wiring pattern, on the substrate in a multilayered state. As a result, level differences are normally formed on the substrate in a stepwise fashion and the wiring pattern is arranged across these level differences.

When the wiring has level differences, it is necessary to increase the wiring width, but when the wiring width is increased, there arises a drawback that a driver load due to wiring parasitic capacitance becomes larger. Therefore, it has been desired to solve these level differences.

Further, when the size of the display device becomes bigger, the wiring pattern itself becomes longer and thus it is necessary to reduce the resistance of the wiring pattern. As techniques for solving the level differences of the wiring pattern and reducing the resistance thereof, Patent Document 1, Japanese Patent Application No. 2005-173050 (referred to as Related Document 1), and Patent Document 2 are proposed, wherein, in order to form wiring for a flat panel display device such as a liquid crystal display device, a wiring pattern is formed on a surface of a transparent substrate and a transparent insulating material having a height equal to that of the wiring pattern is formed in contact with the wiring pattern.

Among them, Patent Document 1 proposes to use an inkjet method or a screen printing method as a wiring forming method. Related Document 1 discloses a method of forming a conductive metal layer for a gate electrode or the like by electroless plating of Cu or the like, while Patent Document 2 discloses a method of more flattening the wiring by heat press or CMP.

Further, Japanese Patent Application No. 2006-313492 (hereinafter referred to as Related Document 2) discloses a TFT and a method of manufacturing it by forming an insulating layer provided with a trench on a substrate, providing a gate electrode in the trench using electroless plating so as to be substantially flush with a surface of the insulating layer, and providing a gate insulating film and a semiconductor layer on the gate electrode. In Patent Document 3, a gate electrode is formed by electroless plating of copper or the like and part of a gate insulating film is formed by spin-coating an insulating coating film. According to this structure, since the insulating coating film formed by spin coating can maintain its surface extremely flat, it is possible to obtain an electronic device such as a TFT excellent in flatness.

### Patent Document 1: WO2004/110117

### Patent Document 2: JP-A-2005-210081

### Patent Document 3: JP-A-2007-43131

### DISCLOSURE OF THE INVENTION

### Problem to be Solved by the Invention

If the wiring is formed by the inkjet method or the screen method as in Patent Document 1, a surface of the wiring becomes rough so that the flatness of an insulating layer or the like formed on the wiring is degraded. On the other hand, if the electroless plating is used as in Related Documents 1 and 2, it is not possible to cope with the increase in size of the display device on a practical level. That is, when the size of a glass substrate is super-enlarged to about 3 m square, a plating apparatus (plating bath) large enough to electroless-plate the super-enlarged glass substrate becomes necessary. However, as a matter of fact, there is no such a large plating apparatus that can plate the super-enlarged glass substrate and, therefore, it is not possible to plate a super-large glass substrate by the use of a plating apparatus. Further, it is practically difficult to uniformly electroless-plate such a super-large area. Moreover, the electroless plating is difficult to control and thus there frequently arises a problem that a circular unplated region is formed in nickel plating on gold plating. Further, when a conductive pattern is formed by electroless plating, it is necessary to provide a layer underlying the plating layer for enhancing the adhesion.

Further, it is extremely difficult to uniformly flatten the wiring on a super-large glass substrate over a wide area using heat press or CMP as in Patent Document 2 and this is also difficult for practical use in terms of economy.

It is therefore a technical object of this invention to provide an electronic device having a conductive pattern uniformly formed on a super-large substrate and a method of manufacturing the electronic device.

It is another technical object of this invention to provide a display device that can be manufactured without using CMP or the like and thus is low-priced and large-sized.

It is still another technical object of this invention to provide a semiconductor device excellent in flatness with a small leakage current.

### Means for Solving the Problem

According to a first aspect of this invention, there is provided a method of manufacturing an electronic device having a substrate, a transparent resin film formed on the substrate, and a metal film selectively buried in the transparent resin film, characterized by comprising a step of forming an insulator coating film on the transparent resin film, a step of forming a trench selectively in the coating film and the transparent resin film, a step of forming a metal film on an entire surface including the inside of the trench and the top of said coating film by sputtering, and a step of lifting off the metal film on the top of said coating film by removing the coating film by etching, thereby obtaining a structure in which the metal film is buried in the trench.

According to a second aspect of this invention, there is provided a method of manufacturing an electronic device according to the first aspect, characterized in that the coating film is porous.

According to a third aspect of this invention, there is provided a method of manufacturing an electronic device according to the first or the second aspect, characterized in that the coating film comprises a porous coating film containing one kind or two or more kinds of oxides of Si, Ti, Al, and Zr.

According to a forth aspect of this invention, there is provided a method of manufacturing an electronic device according to the first aspect, characterized in that the coating film contains one kind or two or more kinds of compositions expressed by ((CH₃)ₙSiO_{2-n/2})ₓ(SiO₂)₁₋ₓ (where n=1 to 3 and x≦1).

According to a fifth aspect of this invention, there is provided a method of manufacturing an electronic device according to the first aspect, characterized in that the step of forming an insulator coating film comprises a step of forming a porous coating film and a step of forming a nonporous coating film on the porous coating film.

According to a sixth aspect of this invention, there is provided a method of manufacturing an electronic device according to any one of the first to the fifth aspects characterized in that the step of forming a trench selectively in the coating film and the transparent resin film comprises a step of providing a photosensitive resist film on the coating film, a step of removing the photosensitive resist film selectively by exposure and development to form a predetermined pattern, and a step of removing the coating film selectively by etching using the predetermined pattern of the photosensitive resist film as a mask.

According to a seventh aspect of this invention, there is provided a method of manufacturing an electronic device according to the sixth aspect, wherein characterized in that the step of forming a trench selectively in the coating film and the transparent resin film further comprises a step of removing the transparent resin film selectively by etching using as a mask at least one of the predetermined pattern of the photosensitive resist film and the remainder of the coating film selectively removed by etching.

According to an eighth aspect of this invention, there is provided a method of manufacturing an electronic device according to the sixth aspect, characterized in that the step of removing the coating film selectively by etching using the predetermined pattern of the photosensitive resist film as a mask comprises a dry etching process using a corrosive gas.

According to a ninth aspect of this invention, there is provided a method of manufacturing an electronic device according to the eighth aspect, characterized in that the step of forming a trench selectively in the coating film and the transparent resin film further comprises a step of removing the transparent resin selectively film by dry etching with the use of the corrosive gas using as a mask at least one of the predetermined pattern of the photosensitive resist film and the remainder of the coating film selectively removed by etching.

According to a tenth aspect of this invention, there is provided a method of manufacturing an electronic device according to the eighth or the ninth aspect, characterized in that the corrosive gas contains a CxFy gas.

According to a eleventh aspect of this invention, there is provided a method of manufacturing an electronic device according to the tenth aspect, characterized in that the corrosive gas contains a CF₄ gas.

According to a twelfth aspect of this invention, there is provided a method of manufacturing an electronic device according to the tenth aspect, characterized in that the corrosive gas contains a C₅F₈ gas and an O₂ gas.

According to a thirteenth aspect of this invention, there is provided a method of manufacturing an electronic device according to according to any one of the first to the twelfth aspects, characterized by further comprising a step of removing the metal film adhering to a side wall of the trench of the coating film after the step of forming the metal film and before removing the coating film by etching.

According to a fourteenth aspect of this invention, there is provided a method of manufacturing an electronic device according to any one of the first to the thirteenth aspects, characterized in that the step of lifting off the metal film on the coating film by removing the coating film by etching, thereby obtaining a structure in which the metal film is buried in the trench comprises a step of removing the coating film by etching using an etching solution containing hydrofluoric acid.

According to a fifteenth aspect of this invention, there is provided a method of manufacturing an electronic device according to any one of the first to the fourteenth aspects, characterized by comprising a step of forming the transparent resin film to a thickness of 1 to 2 μm on the substrate.

According to a sixteenth aspect of this invention, there is provided a method of manufacturing an electronic device according to any one of the first to the fifteenth aspects, characterized in that the step of forming an insulator coating film on the transparent resin film comprises a step of forming the insulator coating film to a thickness of 300 to 2,000 nm.

According to a seventeenth aspect of this invention, there is provided a method of manufacturing an electronic device according to the first aspect, characterized in that the step of forming an insulator coating film on the transparent resin film comprises a step of forming a porous coating film to a thickness of 700 to 1,600 nm and a step of forming a nonporous coating film to a thickness of 100 to 300 nm on the porous coating film.

According to an eighteenth aspect of this invention, there is provided a method of manufacturing an electronic device according to any one of the first to the seventeenth aspects, characterized by comprising a step of forming a semiconductor layer on the selectively buried metal film through an insulating layer therebetween.

### EFFECT OF THE INVENTION

According to this invention, there is obtained a super-large-area and low-priced wiring board or display device having a uniform conductor layer. Further, according to this invention, there are obtained a semiconductor device having a structure in which no level difference due to gate wiring is formed at a TFT channel gate portion, and a method of manufacturing the semiconductor device.

### BRIEF DESCRIPTION OF THE DRAWINGS

FIG. 1 is a sectional view showing one example of the structure of a thin film transistor (TFT) of this invention.

FIG. 2 is a diagram showing a magnetron sputtering apparatus described in Related Document 2.

FIG. 3A is a diagram schematically showing a manufacturing process of a thin film transistor of this invention.

FIG. 3B is a diagram schematically showing a manufacturing process of the thin film transistor of this invention.

FIG. 3C is a diagram schematically showing a manufacturing process of the thin film transistor of this invention.

FIG. 3D is a diagram schematically showing a manufacturing process of the thin film transistor of this invention.

FIG. 3E is a diagram schematically showing a manufacturing process of the thin film transistor of this invention.

FIG. 3F is a diagram schematically showing a manufacturing process of the thin film transistor of this invention.

FIG. 3G is a diagram schematically showing a manufacturing process of the thin film transistor of this invention.

FIG. 4A is a sectional view for use in explanation of a lift-off simple test used in this invention.

FIG. 4B is a sectional view for use in explanation of the lift-off simple test used in this invention.

FIG. 4C is a sectional view for use in explanation of the lift-off simple test used in this invention.

FIG. 4D is a sectional view for use in explanation of the lift-off simple test used in this invention.

FIG. 4E is a sectional view for use in explanation of the lift-off simple test used in this invention.

FIG. 4F is a sectional view for use in explanation of the lift-off simple test used in this invention.

FIG. 5 is optical microscope photographs showing time-dependent changes of a surface when a glass substrate 10 was immersed in a lift-off solution.

FIG. 6 is a graph showing the relationship between the thickness of a porous-type insulating coating film and the time to lift off aluminum wiring of 100 μm.

FIG. 7A is a diagram schematically showing a manufacturing process of a thin film transistor of this invention.

FIG. 7B is a diagram schematically showing a manufacturing process of the thin film transistor of this invention.

FIG. 7C is a diagram schematically showing a manufacturing process of the thin film transistor of this invention.

FIG. 7D is a diagram schematically showing a manufacturing process of the thin film transistor of this invention.

FIG. 7E is a diagram schematically showing a manufacturing process of the thin film transistor of this invention.

FIG. 7F is a diagram schematically showing a manufacturing process of the thin film transistor of this invention.

FIG. 7G is a diagram schematically showing a manufacturing process of the thin film transistor of this invention.

FIG. 7H is a diagram schematically showing a manufacturing process of the thin film transistor of this invention.

FIG. 7I is a diagram schematically showing a manufacturing process of the thin film transistor of this invention.

FIG. 7J is a diagram schematically showing a manufacturing process of the thin film transistor of this invention.

FIG. 7K is a diagram schematically showing a manufacturing process of the thin film transistor of this invention.

### DESCRIPTION OF SYMBOLS

10 glass substrate (insulating substrate)
11 transparent resin film (transparent resist)
12 aluminum film (gate electrode)
12a trench
14 gate insulating film
141, 14a, 14b insulating coating film
142 dielectric film
15 g-line resist film
161 semiconductor layer
162 semiconductor layer
17 source electrode
18 drain electrode
19 patterning resist
20 insulating film (Si₃N₄)
50 magnetron sputtering apparatus
51 target
52 columnar rotary shaft
53 helical plate-like magnet group (rotary magnet group)
54 fixed outer circumferential frame magnet
55 outer peripheral paramagnetic member
56 backing plate
58 passage
59 insulating member
60 substrate
61 process chamber space
62 feeder line
63 cover
64 outer wall
65 paramagnetic member
66 plasma shielding member
71 vertically movable mechanism
112 Cu film
112-1 Cu film
112-2 Cu film
112-3 Cu film
114 porous insulating coating film
124 nonporous insulating coating film

### BEST MODE FOR CARRYING OUT THE INVENTION

Hereinbelow, embodiments of this invention will be described.

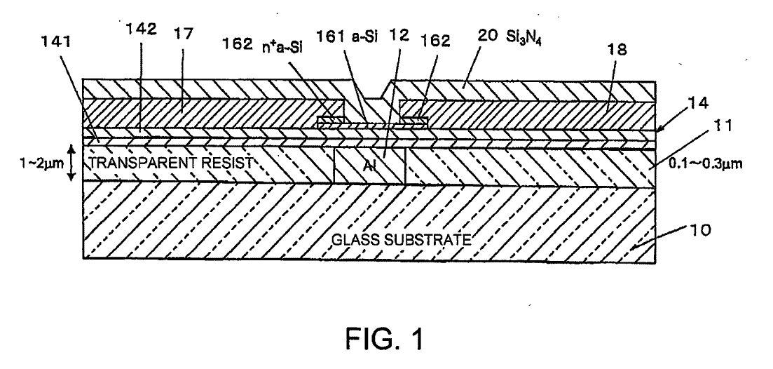

FIG. 1 is a sectional view showing one example of the structure of a TFT according to this invention. The illustrated TFT has a glass substrate (insulating substrate) 10, a transparent resin film (transparent resist) 11 of a transparent photosensitive resin formed on the glass substrate 10, and a gate electrode 12 formed in a trench, selectively formed in the transparent resin film 11 to reach the glass substrate 10, so as to extend to approximately the same height as the transparent resin film 11. The transparent resin film 11 has a thickness of 1 to 2 μm and is preferably formed by a transparent resin film described in Patent Document 3. In the illustrated example, the transparent resin film 11 is formed directly on a surface of the glass substrate 10 and thus there is no underlayer provided therebetween.

The gate electrode 12 of FIG. 1 is an aluminum (Al) electrode formed by sputtering and is formed using a later-described sputtering apparatus. The gate electrode 12 is formed, without performing CMP, by selectively removing aluminum other than in the trench (i.e. over the transparent resin film 11) using a lift-off technique according to this invention. In this manner, in this invention, since the gate electrode 12 is formed by sputtering, it is possible to form the gate electrode with higher adhesion as compared with an electrode formed by electroless plating. Further, in this invention, since the gate electrode 12 is formed using the sputtering apparatus that enables sputtering over a large area, even if the glass substrate has a large size of about 3 m×3 m, the gate electrode 12 can be uniformly formed on the glass substrate and, further, extra aluminum other than in the trench is removed by the lift-off. The gate electrode 12 may alternatively be Cu formed by sputtering.

The illustrated TFT has an insulating coating film 141 uniformly formed on the transparent resin film 11 and the gate electrode 12 so as to lie over them. The insulating coating film 141 is formed by a coating film disclosed in Related Document 2. This insulating coating film 141 is formed by spin-coating a coating solution in the form of a mixture of a complex of polymethylsilsesquioxane and silica and a solvent and then drying it. The coating solution is a liquid in the spin-coated state described above and, therefore, in the state where the glass substrate 10 is maintained horizontal, a surface of the solution after the coating is also maintained horizontal. Further, even if a gap exists between the transparent resin film 11 and the gate electrode 12, the coating solution also flows into the gap and, as a result, the surface of the solution after the coating is maintained horizontal. Even if dried in this state, the insulating coating film (hereinafter, the insulating coating film and its composition may respectively be abbreviated as a SiCO film) 141 maintains high flatness and thus can also be called a flattening film. The insulating coating film 141 coated and dried has a surface roughness of 0.27 μm or less in average surface roughness Ra and a permittivity ∈r of to 5.0.

A dielectric film 142 such as a silicon nitride film is formed by CVD on the insulating coating film 141. As a result, the illustrated TFT has an insulating layer 14 including a gate insulating film formed by the insulating coating film 141 and the dielectric film 142.

Further, the illustrated TFT has a semiconductor layer 161 of amorphous silicon (a-Si) formed on the insulating layer 14, semiconductor layers 162 of n⁺a-Si formed on the semiconductor layer 161, and source and drain electrodes 17 and 18 of a metal formed on the semiconductor layers 162. The semiconductor layer 161 forms a channel region. Further, an insulating film 20 of silicon nitride (Si₃N₄) is formed on the source electrode 17, the drain electrode 18, and the channel region.

In this structure, since the gate electrode 12 is formed by sputtering, the gate electrode with good adhesion to the glass substrate 10 can be formed and, further, since aluminum over the transparent resin film 11 is removed by the lift-off (chemical lift-off) technique, the manufacturing cost can be significantly reduced as compared with removal using CMP.

Next, referring to FIG. 2, a sputtering film forming method of the gate electrode 12 according to this invention will be described. Herein, a description will be given of the case where the gate electrode 12 is formed of aluminum. FIG. 2 shows a magnetron sputtering apparatus having the same structure as that of a magnetron sputtering apparatus described in Japanese Patent Application No. 2007-92058 (hereinafter referred to as Related Document 3).

A magnetron sputtering apparatus 50 shown in FIG. 2 has a target 51, a columnar rotary shaft 52, a plurality of helical plate-like magnet groups (i.e. a rotary magnet group) 53 helically disposed on a surface of the rotary shaft 52, a fixed outer circumferential frame magnet 54 disposed around the rotary magnet group, an outer peripheral paramagnetic member 55 disposed on the side opposite to the target 51 so as to face the fixed outer circumferential frame magnet 54, a backing plate 56 of copper to which the target 51 is bonded, a paramagnetic member 65 configured to cover the columnar rotary shaft 52 and the helical plate-like magnet groups 53 at portions thereof other than on the target side, a passage 58 for passing a coolant therethrough, an insulating member 59, a substrate (to be processed) 60, a placing stage 69 for placing the substrate 60 thereon, a process chamber space 61, a feeder line 62, a cover 63 electrically connected to a process chamber, outer walls 64 forming the process chamber, a plasma shielding member 66 disposed on the outer wall 64 so as to be electrically connected thereto, and an insulating member 67 excellent in plasma resistance.

The plasma shielding member 66 forms a slit extending in an axial direction of the columnar rotary shaft 52 and opening the target 51 with respect to the substrate 60. In this case, the width and the length of the slit of the plasma shielding member 66 are set so that when the rotary magnet group 53 is rotated at a constant frequency, a region where the magnetic field strength is 75% or more of the maximum value in the time average distribution of magnetic field strengths of components parallel to a surface of the target 51 in a magnetic field formed on the surface of the target 51 is opened as seen from the substrate 60. Simultaneously, the width and the length of the slit are set so that a region of the substrate 60 where the film thickness to be formed per unit time is 80% or less of the maximum film thickness to be formed on the substrate 60 per unit time when end portions of the target 51 are not shielded is shielded by the plasma shielding member 66. A region not shielded by the plasma shielding member 56 is a region where the magnetic field strength is high and thus a plasma with a high density and a low electron temperature is generated so that there is no charge-up damage or ion irradiation damage to the substrate 60, and is simultaneously a region where the film forming rate is high. By shielding the region other than this region by the shielding member 66, it is possible to carry out film formation with no damage without substantially reducing the film forming rate.

On the other hand, a DC power supply, a RF power supply, and a matching device are connected to the feeder line 62. The plasma excitation power is supplied to the backing plate 56 and the target 51 from the DC power supply and the RF power supply through the matching device and further through the feeder line 62 and the housing so that a plasma is excited on the surface of the target. A plasma can be excited only by the DC power or the RF power, but in terms of the film quality controllability and the film forming rate controllability, it is preferable to apply both.

The frequency of the RF power is normally selected between several hundred kHz and several hundred MHz, but in terms of increasing the plasma density and reducing the plasma electron temperature, a high frequency is preferable. In this embodiment, it is set to 13.56 MHz. The plasma shielding member 66 also functions as a ground plate for the RF power. With this ground plate, even if the substrate 60 is in an electrically floating state, a plasma can be efficiently excited. The paramagnetic member 65 has an effect of magnetic shielding of a magnetic field generated by the magnets and an effect of reducing a change in magnetic field due to disturbance near the target. Further, a non-illustrated vertically movable mechanism driven by a motor is provided in a region inside a dotted line 71.

By setting an aluminum target as the target 51 of the illustrated magnetron sputtering apparatus 50 and setting as the substrate 60 the glass substrate 10 having the transparent resin film 11 selectively formed with the trench as shown in FIG. 1, an aluminum film for the gate electrode (and gate wiring) 12 is formed. Since the illustrated magnetron sputtering apparatus 50 is suitable for uniform film formation of the material of the target 51 on the large-area substrate 60, the aluminum film is uniformly formed over the transparent resin film 11 and on the glass substrate 10 in the trench.

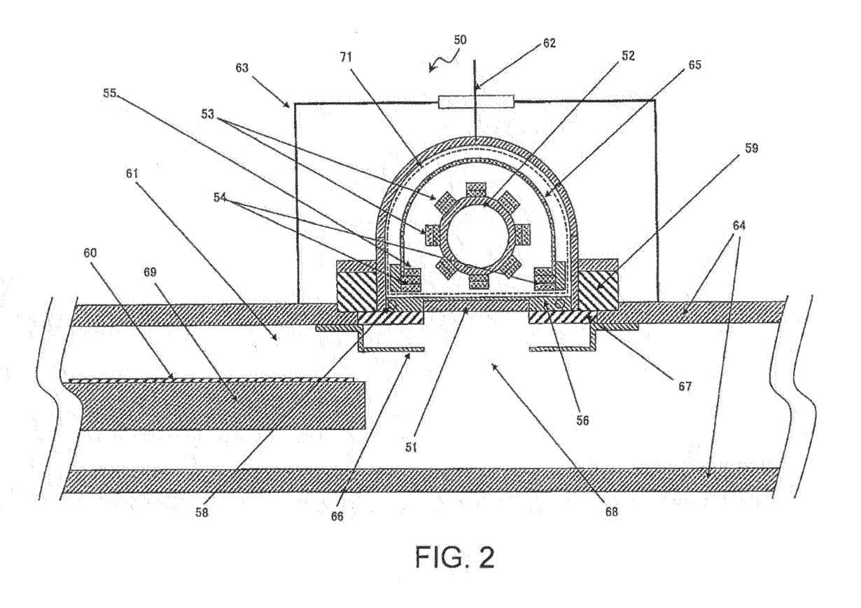

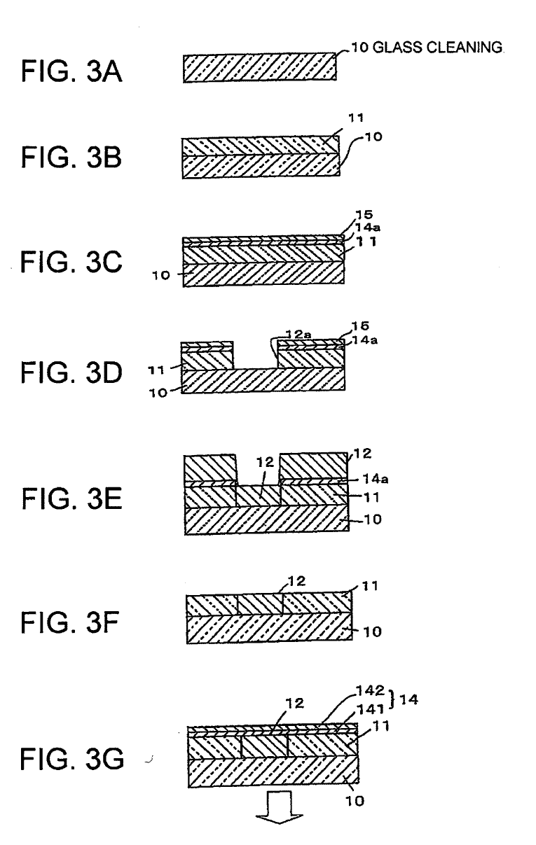

Next, processes up to forming the insulating coating film 141 and the dielectric film 142 to form the insulating layer 14 after forming the transparent resin film 11 on the glass substrate 10 as shown in FIG. 1 will be described with reference to FIGS. 2 and 3.

First, as shown in FIG. 3A, the glass substrate 10 is cleaned and, then, as shown in FIG. 3B, a transparent resin film is coated on the glass substrate 10 and heat-treated, thereby providing the transparent resin film 11 having a thickness of 1,000 nm. The thickness may alternatively be about 2,000 nm.

Then, as shown in FIG. 3C, an insulating coating film 14a is coated on the transparent resin film 11 and heat-treated. In this case, the illustrated insulating coating film 14a is preferably a coating film having a compound composition expressed by ((CH₃)ₙSiO_{2-n/2})ₓ(SiO₂)₁₋ₓ (where n=1 to 3 and x≦1). The insulating coating film 14a can also be called a first coating film. Alternatively, the insulating coating film 14a can be a porous coating film containing one kind or two or more kinds of oxides of Si, Ti, Al, and Zr. The thickness of the insulating coating film 14a is suitably 300 to 2,000 nm. In this example, it is set to 700 nm. Further, thereon, a g-line resist film 15 is formed to a thickness of 400 to 2,000 nm. The g-line resist film 15 is exposed and developed, thereby exposing a surface of the insulating coating film 14a at portions to be a trench.

Then, as shown in FIG. 3D, using the g-line resist film 15 as a mask, the insulating coating film 14a and the transparent resin film 11 are selectively etched to form a trench 12a, reaching the glass substrate 10, in the transparent resin film 11 and the insulating coating film 14a. The etching may be wet etching, but in this example, dry etching is performed using a plasma etching apparatus. In dry etching using a CF₄ gas, the etching of the insulating coating film 14a and the transparent resin film 11 can be performed with a selectivity of 1.5. In dry etching using an O₂/C₅F₈ gas, the etching of the insulating coating film 14a and the transparent resin film 11 can be performed with a selectivity of 1.7. In each case, side walls of the trench are etched vertically. In the case where the insulating coating film 14a is a porous-type coating film, unevenness is observed on the side walls, but in the case where the insulating coating film 14a is formed by a porous-type coating film with a thickness of 700 nm and a nonporous-type coating film with a thickness of 100 to 300 nm provided on the porous-type coating film, smooth side walls are obtained. The g-line resist film 15 is preferably removed by ashing after forming the trench.

The glass substrate 10 formed with the trench 12a is introduced into the magnetron sputtering apparatus shown in FIG. 2. In the magnetron sputtering apparatus provided with the aluminum target as the target 51, an aluminum film 12 is formed by sputtering in the trench 12a and over the entire surface of the insulating coating film 14a as shown in FIG. 3E. The aluminum film 12 formed by sputtering in this manner exhibits excellent adhesion to the glass substrate 10. Further, using the magnetron sputtering apparatus shown in FIG. 2, the aluminum film 12 can be uniformly formed even on the 3 m×3 m square super-large substrate.

The glass substrate 10 formed with the aluminum film 12 is removed from the magnetron sputtering apparatus 50 and introduced into an apparatus for chemical lift-off. In the chemical lift-off, the insulating coating film 14a is etched with a SiO₂-based selective etching solution (containing hydrofluoric acid) and simultaneously the aluminum film 12 on the insulating coating film 14a is removed by lift-off. As a result, as shown in FIG. 3F, the aluminum film 12 remains only in the trench 12a of the transparent resin film 11 so that the gate electrode (or gate wiring) 12 is formed. In this case, a surface of the transparent resin film 11 and a surface of the gate electrode (or gate wiring) 12 form substantially the same plane. That is, the transparent resin film 11 and the gate electrode (or gate wiring) 12 have substantially the same thickness.

Then, as shown in FIG. 3G, the insulating coating film 141 is coated by spin coating as a second coating film and subsequently the dielectric film 142 is formed, thereby forming the insulating layer 14 as a gate insulating film. As the dielectric film 142, a silicon nitride film (Si₃N₄) is formed by CVD. Thereafter, TFT manufacturing processes are carried out. The same film as the first coating film 14a can be used as the second coating film 141.

In the above-mentioned example, the ordinary photoresist is provided on the insulating coating film 14a and, using it as a mask, the insulating coating film 14a and the transparent resin film 11 are etched by dry etching for patterning. However, the insulating coating film 14a may be photosensitive and, after patterning the insulating coating film 14a itself by mask exposure, the transparent resin film 11 may be patterned using the patterned insulating coating film 14a as a mask.

This invention is not limited to these techniques. For example, an ordinary photoresist is provided on the insulating coating film 14a and, using it as a mask, the insulating coating film 14a may be wet-etched with an etching solution, and then, using the etched insulating coating film 14a as a mask, the transparent resin film 11 may be wet-etched for patterning.

As described above, the trench 12a shown in FIG. 3D may be formed using any method.

The lift-off process described with reference to FIGS. 3E and F is such that the insulating coating film 14a is coated on the transparent resin film 11 and the insulating coating film 14a is lifted off along with the aluminum film 12.

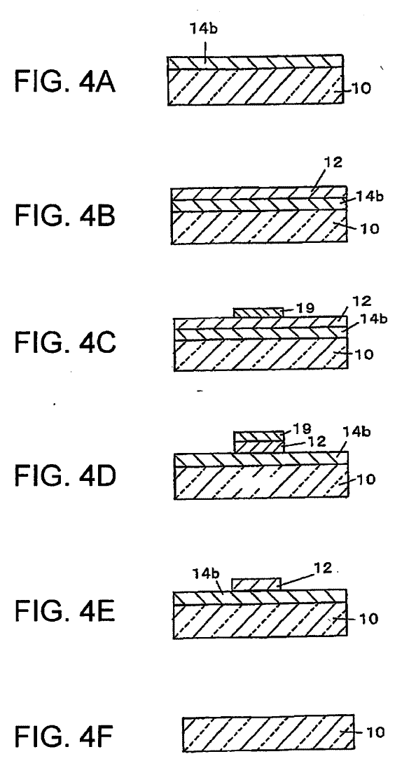

Next, referring to FIG. 4, the etching rate of an aluminum film following lift-off of an insulating coating film will be described. For this purpose, there was prepared a sample in which an insulating coating film 14b was coated on a glass substrate 10 as shown in FIG. 4A and an aluminum film 12 was formed on the insulating coating film 14b as shown in FIG. 4B. The illustrated insulating coating film 14b had a thickness of 400 nm and was a nonporous-type coating film. The insulating coating film 14b was heat-treated (baked and annealed) in a N₂ atmosphere at 300° C. for 1 hour.

On the insulating coating film 14b, the aluminum film 12 was formed using the magnetron sputtering apparatus shown in FIG. 2 (FIG. 4B). Then, as shown in FIG. 4C, a patterning resist 19 was coated on the aluminum film 12 and patterned and, as shown in FIG. 4D, using the patterning resist 19 as a mask, the aluminum film 12 was patterned to a width of 100 μm with the use of a phosphoric acid/nitric acid/acetic acid mixed solution.

Subsequently, as shown in FIG. 4E, after stripping the patterning resist, the glass substrate 10 having the insulating coating film 14b and the patterned aluminum film 12 was immersed in a lift-off solution (23° C.). As the lift-off solution, use was made of an HF-based etching solution having a microroughness suppression effect on an aluminum surface. As a result, as shown in FIG. 4F, the aluminum film 12 on the insulating coating film 14b was removed by etching along with the insulating coating film 14b.

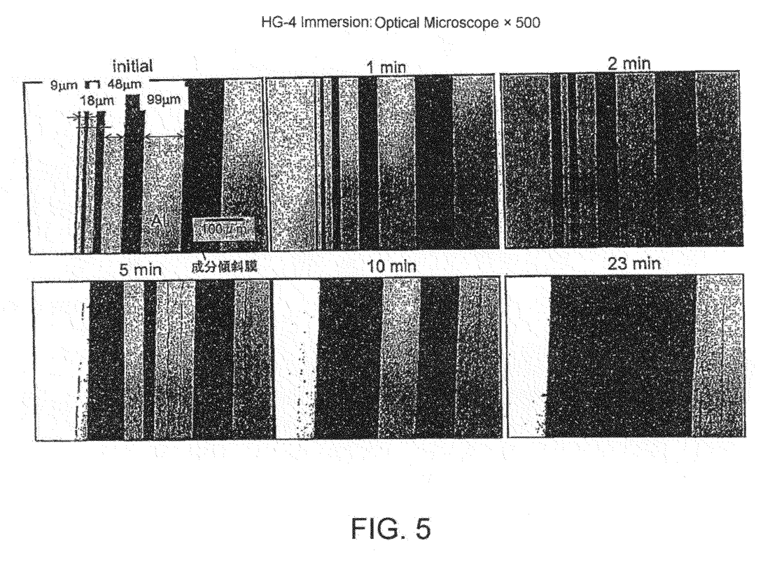

FIG. 5 is optical microscope photographs showing time-dependent changes of a surface when immersed in the lift-off solution. FIG. 5 shows the results of observation using an optical microscope of 500 magnifications after immersion for 0 minutes, 1 minute, 2 minutes, 5 minutes, 10 minutes, and 23 minutes in the lift-off solution. As is clear from FIG. 5, the aluminum wiring of 100 μm was lifted off after the immersion for 23 minutes. Accordingly, the etching rate of the aluminum wiring was 0.07 μm/sec.

Then, in order to increase the etching rate, the composition expressed by ((CH₃)ₙSiO_{2-n/2})ₓ(SiO₂)₁₋ₓ (where n=1 to 3 and x≦1) of the insulating coating film was improved. In this case, the insulating coating film containing the composition expressed by ((CH₃)ₙSiO_{2-n/2})ₓ(SiO₂)₁₋ₓ (where n=1 to 3 and x≦1) was changed to a porous-type coating film. That is, the insulating coating film was changed to a porous coating film containing one kind or two or more kinds of oxides of Si, Ti, Al, and Zr (hereinafter referred to simply as porous-type). As a result of comparison, it was found that the etching rate of the porous-type SiCO film was 0.5 μm/sec and thus was seven times that of the nonporous SiCO film.

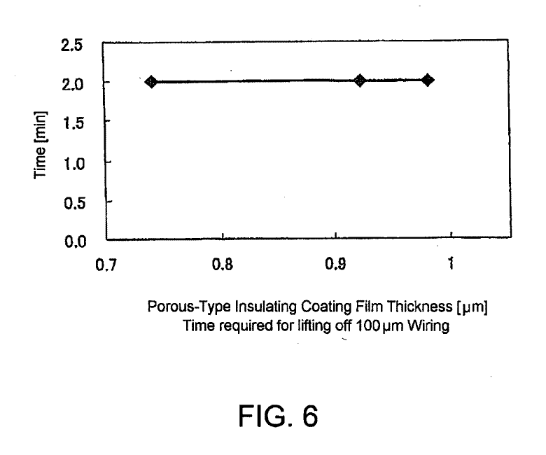

Referring to FIG. 6, it is a graph showing the relationship between the time required for lifting off aluminum wiring having a width of 100 μm and the thickness of a porous-type insulating coating film. The time required for lifting off aluminum wiring having a width of 100 μm was measured by setting the thicknesses of porous-type insulating coating films to 0.74 μm, 0.92 μm, and 0.98 μm and, as a result, the aluminum wiring was removed in 2 minutes regardless of the thickness of the insulating coating film as illustrated. Therefore, it is seen that making the insulating coating film porous is quite effective for increasing the etching rate.

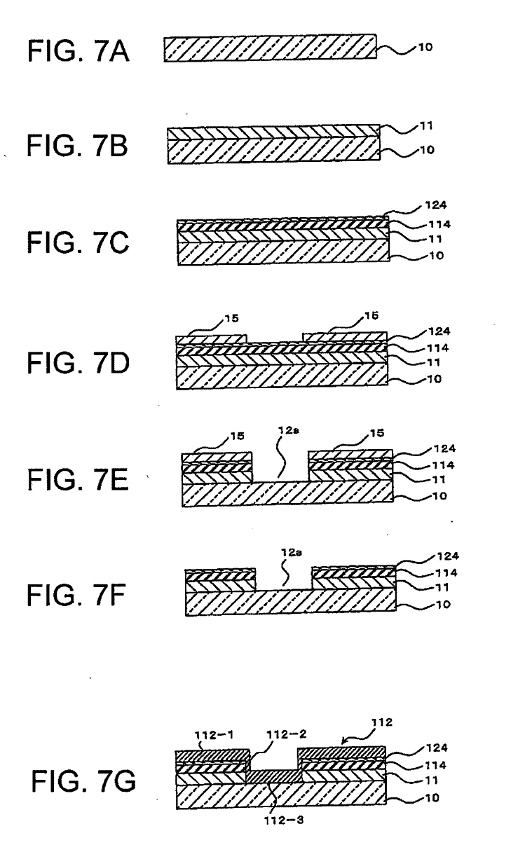

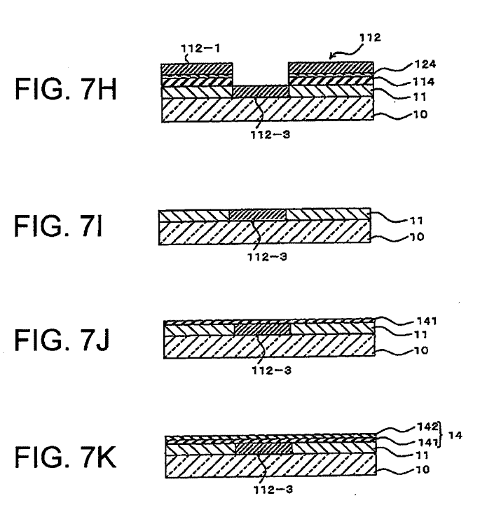

Next, in the structure shown in FIG. 1, another embodiment of processes up to forming the insulating coating film 141 and the dielectric film 142 to form the insulating layer 14 after forming the transparent resin film 11 on the glass substrate 10 will be described with reference to FIG. 7.

First, as shown in FIG. 7A, the glass substrate 10 is cleaned and, then, as shown in FIG. 7B, a high-temperature heat-resistant transparent resin (e.g. cycloolefin polymer) is coated on the glass substrate 10 and heat-cured, thereby providing the heat-resistant transparent organic film 11 having a thickness of 1,000 nm to 2,000 nm (e.g. 1,000 nm).

Then, as shown in FIG. 7C, a porous insulating coating film 114 is coated on the transparent resin film 11 and heat-cured and, then, a nonporous insulating coating film 124 is coated thereon and heat-cured. The porous insulating coating film 114 is spin-coated or coated using a slit coater, pre-baked at 120° C. for 90 seconds, and then baked in a nitrogen atmosphere at 300° C. for 1 hour. The thickness is suitably 700 to 1,600 nm. In this example, it is set to 750 nm. The nonporous insulating coating film 124 is spin-coated or coated using a slit coater, pre-baked at 120° C. for 90 seconds, and then baked in a nitrogen atmosphere at 300° C. for 2 hours. The thickness is suitably 100 to 300 nm. In this example, it is set to 140 nm. By providing the nonporous insulating coating film 124, a surface becomes smoother so that it is possible to prevent the occurrence of roughness (unevenness) in an edge pattern of a resist film provided thereon. That is, finer patterning is enabled.

Then, as shown in FIG. 7D, a g-line resist film 15 is formed to a thickness of 400 to 2,000 nm on the nonporous insulating coating film 124. The g-line resist film 15 is exposed and developed, thereby exposing a surface of the nonporous insulating coating film 124 at portions to be a trench.

Then, as shown in FIG. 7E, using the g-line resist film 15 as a mask, the nonporous insulating coating film 124, the porous insulating coating film 114, and the transparent resin film 11 are selectively etched to form a trench 12a, reaching the glass substrate 10, in a lift-off layer (the nonporous insulating coating film 124+ the porous insulating coating film 114) and the transparent resin film 11. The etching is performed by dry etching using a plasma etching apparatus. Then, as shown in FIG. 7F, the g-line resist film 15 is removed by ashing.

The glass substrate 10 of FIG. 7F formed with the trench 12a is introduced into the magnetron sputtering apparatus shown in FIG. 2. In the magnetron sputtering apparatus provided with a copper target as the target 51, as shown in FIG. 7G, a Cu film 112 is continuously formed by sputtering on the surface of the glass substrate in the trench 12a so as to be as thick as the transparent resin film 11 as indicated at 112-3, on side walls of the lift-off layer (the nonporous insulating coating film 124+ the porous insulating coating film 114) in the trench 12a as indicated at 112-2, and over the entire surface of the nonporous insulating coating film 124 as indicated at 112-1. By properly selecting the DC voltage, the RF frequency, and so on in the sputtering to promote migration of Cu, the Cu film 112-3 in the trench 12a can be formed to a substantially uniform thickness from its central portion to its end portions. However, it cannot be avoided that the Cu film 112-2 is formed also on the side walls of the lift-off layer. Therefore, as shown in FIG. 7H, as a next process, the Cu film 112-2 on the side walls of the lift-off layer is removed by etching. Specifically, the glass substrate 10 formed with the Cu film 112 is removed from the magnetron sputtering apparatus 50 and carried into an apparatus for wet etching, wherein the Cu film 112-2 on the side walls of the lift-off layer is removed by etching using an etching solution containing sulfuric acid, hydrogen peroxide, and pure water in a volume ratio of 1:1:38. Herein, when a sputtering metal is Al, use is made of an etching solution containing phosphoric acid, nitric acid, acetic acid, and pure water.

Then, as shown in FIG. 7I, the lift-off layer (the nonporous insulating coating film 124+ the porous insulating coating film 114) is etched by immersion in a buffered hydrofluoric acid at 23° C. for 4 minutes, thereby removing the Cu film 112-1 thereon by lift-off. As a result, as shown in FIG. 7I, the Cu film 112-3 remains only in the trench 12a of the transparent resin film 11, which is used as the gate electrode (or gate wiring). Herein, a surface of the transparent resin film 11 and a surface of the Cu film 112-3 form substantially the same plane. That is, both have substantially the same thickness.

Then, as shown in FIG. 7J, the insulating flattening coating film 141 is spin-coated or coated using a slit coater and, then, as shown in FIG. 7K, the silicon nitride film (SiNₓ) 142 is formed by CVD so that the formation of the gate insulating film 14 is finished. Thereafter, TFT manufacturing processes are carried out.

As described above, according to this invention, since the lift-off process is used, it is possible to manufacture a Flat-TFT having a gate electrode with no level difference. Therefore, according to this invention, a thorough reduction in off-leakage current can be achieved, the mobility of a channel can be improved, and further, since the thickness of a gate wiring film can be increased, the wiring width can be reduced so that it is possible to achieve a reduction in driver load by a reduction in wiring parasitic capacitance.

Further, according to this invention, it is possible to suppress variation in threshold voltage of TFTs and to obtain a low power consumption TFT. Further, according to this invention, it is also possible to obtain a TFT with high current driving capability and thus to realize an increase in panel size and image quality of a display device.

### INDUSTRIAL APPLICABILITY

As described above, a thin film electronic device and its manufacturing method of this invention can be applied to an organic EL element, an inorganic EL element, a liquid crystal display, and the like and the manufacture thereof.

1. A method of manufacturing an electronic device having a substrate, a transparent resin film formed on said substrate, and a metal film selectively buried in said transparent resin film, by comprising:
a step of forming an insulator coating film on the top of said transparent resin film,
a step of forming a trench selectively in said coating film and said transparent resin film,
a step of forming a metal film on an entire surface including the inside of said trench and the top of said coating film by sputtering, and
a step of lifting off said metal film on the top of said coating film by removing said coating film by etching, thereby obtaining a structure in which said metal film is buried in said trench.

2. A method of manufacturing an electronic device according to claim 1, wherein said coating film is porous.

3. A method of manufacturing an electronic device according to claim 1, wherein said coating film comprises a porous coating film containing one kind or two or more kinds of oxides of Si, Ti, Al, and Zr.

4. A method of manufacturing an electronic device according to claim 1, wherein said coating film contains one kind or two or more kinds of compositions expressed by ((CH₃)ₙSiO_{2-n/2})ₓ(SiO₂)₁₋ₓ (where n=1 to 3 and x≦1).

5. A method of manufacturing an electronic device according to claim 1, wherein said step of forming an insulator coating film comprises a step of forming a porous coating film and forming a nonporous coating film on said porous coating film.

6. A method of manufacturing an electronic device according to claim 1, wherein said step of forming a trench selectively in said coating film and said transparent resin film comprises a step of providing a photosensitive resist film on said coating film, a step of removing said photosensitive resist film selectively by exposure and development to form a predetermined pattern, and a step of removing said coating film selectively by etching using said predetermined pattern of said photosensitive resist film as a mask.

7. A method of manufacturing an electronic device according to claim 6, wherein said step of forming a trench selectively in said coating film and said transparent resin film further comprises a step of removing said transparent resin film selectively by etching using as a mask at least one of said predetermined pattern of said photosensitive resist film and the remainder of said coating film selectively removed by etching.

8. A method of manufacturing an electronic device according to claim 6, wherein said step of removing said coating film selectively by etching using said predetermined pattern of said photosensitive resist film as a mask comprises a dry etching process using a corrosive gas.

9. A method of manufacturing an electronic device according to claim 8, wherein said step of forming a trench selectively in said coating film and said transparent resin film further comprises a step of removing said transparent resin selectively film by dry etching with the use of said corrosive gas using as a mask at least one of said predetermined pattern of said photosensitive resist film and the remainder of said coating film selectively removed by etching.

10. A method of manufacturing an electronic device according to claim 8, wherein said corrosive gas contains a CxFy gas.

11. A method of manufacturing an electronic device according to claim 10, wherein said corrosive gas contains a CF₄ gas.

12. A method of manufacturing an electronic device according to claim 10, wherein said corrosive gas contains a C₅F₈ gas and an O₂ gas.

13. A method of manufacturing an electronic device according of claim 1, further comprising a step of removing said metal film adhering to a side wall of said trench of said coating film after said step of forming said metal film and before removing said coating film by etching.

14. A method of manufacturing an electronic device according to claim 1, wherein said step of lifting off said metal film on said coating film by removing said coating film by etching, thereby obtaining a structure in which said metal film is buried in said trench comprises a step of removing said coating film by etching using an etching solution containing hydrofluoric acid.

15. A method of manufacturing an electronic device according to claim 1, comprising a step of forming said transparent resin film to a thickness of 1 to 2 μm on said substrate.

16. A method of manufacturing an electronic device according to of claim 1, wherein said step of forming an insulator coating film on said transparent resin film comprises a step of forming said insulator coating film to a thickness of 300 to 2,000 nm.

17. A method of manufacturing an electronic device according to claim 1, wherein said step of forming an insulator coating film on said transparent resin film comprises a step of forming a porous coating film to a thickness of 700 to 1,600 nm and forming a nonporous coating film to a thickness of 100 to 300 nm on said porous coating film.

18. A method of manufacturing an electronic device according to claim 1, comprising a step of forming a semiconductor layer on said selectively buried metal film through an insulating layer therebetween.
